(19) United States
(12) Patent Application Publication
(10) Pub. No.: US 2019/0229103 A1
(43) Pub. Date: Jul. 25, 2019

(54) SEMICONDUCTOR DEVICE

(71) Applicants: WASEDA UNIVERSITY, Tokyo (JP); MITSUI HIGH -TEC., INC., Fukuoka (JP); TOYOTA JIDOSHA KABUSHIKI KAISHA, Aichi-ken (JP)

(72) Inventors: Kohei TATSUMI, Tokyo (JP); Kazuhito KAMEI, Tokyo (JP); Rikiya Kamimura, Fukuoka (JP); Koji SHIMIZU, Fukuoka (JP); Kazutoshi UEDA, Fukuoka (JP); Nobuaki SATO, Fukuoka (JP); Keiji TODA, Aichi-ken (JP); Masayuki HIKITA, Fukuoka (JP); Akihiro IMAKIIRE, Fukuoka (JP)

(73) Assignees: WASEDA UNIVERSITY, Tokyo (JP); MITSUI HIGH-TEC., INC., Fukuoka (JP); TOYOTA JIDOSHA KABUSHIKI KAISHA, Aichi-ken (JP)

(21) Appl. No.: 16/257,722

(22) Filed: Jan. 25, 2019

Related U.S. Application Data
(63) Continuation-in-part of application No. PCT/JP2017/036348, filed on Oct. 5, 2017.

(30) Foreign Application Priority Data
Oct. 12, 2016 (JP) 2016201095

(51) Int. Cl. H01L 25/18; H01L 23/367; H01L 23/00; H05K 7/20

(52) U.S. Cl. CPC H01L 25/18; H02M 7/537; H01L 24/32; H01L 24/33; H01L 24/16; H01L 24/17; H05K 7/209; H01L 2224/16245; H01L 2224/17181; H01L 2224/16014; H01L 2224/13147; H01L 2224/13655; H01L 2224/05647; H01L 2224/32245; H01L 2224/33181; H01L 2224/29155; H01L 2924/10272; H01L 2924/1033; H01L 2924/1203; H01L 2924/13091; H01L 23/367

(57) ABSTRACT

A semiconductor device includes: a first switching element that is provided on a high side; a first diode element that is connected in parallel to the first switching element; a second switching element that is provide on a low side and connected in series to the first switching element; and a second diode element that is connected in parallel to the second switching element, wherein the first switching element and one of the first diode element and the second diode element are stacked adjacently to each other in a vertical direction of respective electrode surfaces thereof via a conductive electrode, the second switching element and the other of the first diode element and the second diode element that is different from the diode element adjacent to the first switching element are stacked adjacently to each other in a vertical direction of respective electrode surfaces thereof via a conductive electrode, and the first switching element and the second switching element are not adjacent in a vertical direction of respective electrode surfaces thereof.

### CROSS REFERENCE TO RELATED APPLICATIONS

This application is a continuation in-part of International Patent Application No. PCT/JP2017/036348, filed on Oct. 5, 2017, now pending, the contents of which, including the specification, the claims, and the drawings, are incorporated herein by reference in their entirety. International Patent Application No. PCT/JP2017/036348 is entitled to the benefit of Japanese Patent Application No. 2016-201095, filed on Oct. 12, 2016, the contents of which, including the specification, the claims, and the drawings, are incorporated herein by reference in their entirety.

### BACKGROUND ART

### Technical Field

The present invention relates to a semiconductor device constituting a switching circuit having a stacked structure.

Switching power supply circuits using switching elements on both a high side and a low side are generally known. For example, as a configuration of a general switching power supply circuit, a circuit configuration of a switching element including diodes connected in reversely parallel to switching elements on both a high side and a low side is disclosed (see, for example, JP 2013-66371 A, which is hereinafter referred to as “Patent Literature 1”).

Such a general switching power supply circuit is planarly mounted due to restrictions in mounting and the like, so that a projected area of a current loop from an input terminal through a semiconductor element to an output terminal cannot help but be increased. That is, a parasitic inductance which is proportional to the projected area of the current loop of the switching power supply circuit also has a large value, resulting in a problem that a switching loss increases.

In relation to such a problem, JP 2008-108912 A (hereinafter referred to as “Patent Literature 2”) discloses a configuration of a stacked semiconductor device obtained by stacking a plurality of power transistors each having a drain electrode on a first main surface side and a source electrode and a gate electrode on a second main surface side, in which the drain electrode, the source electrode and the gate electrode of each power transistor are electrically connected to respective bus bars, and opposing main surface sides of the stacked power transistors are connected with each other to a common bus bar. In particular, Patent Literature 2 discloses a circuit configuration of the semiconductor device in which a plurality of power transistors arranged in parallel are stacked in two layers, and reflux diodes corresponding to the respective power transistors are provided in combination with the respective power transistors. However, Patent Literature 2 does not disclose a specific stacked structure in which diodes are provided together, as a package structure.

Note that Patent Literature 2 discloses solder connection as a method of connection in the stacked structure. However, solder connection in a stacked structure involves simultaneous melting of metals, so that it is an extremely difficult and expensive connection technology as a production process such as temperature control and gap adjustment of respective connections.

On the other hand, WO 2015/053356 A1 (hereinafter referred to as “Patent Literature 3”) discloses a technique using plating as a technology for connecting electrodes in a stacked structure. Patent Literature 3 discloses a technique in which that at least a part of a plurality of electrodes, of an electric circuit, to be electrically connected is directly or indirectly brought into contact, and connected by plating between the electrodes in a state where a plating solution is circulated around the contact portion.

However, in the technique disclosed in Patent Literature 2, it is possible to reduce a value of the parasitic inductance proportional to the projected area of the current loop by forming the power transistor in the stacked structure, and as a result, it is possible to suppress a switching loss, but since the power transistors are stacked in a vertical direction, there is a problem that the power transistors as heat generating parts are mounted in a narrow region where they are extremely close to each other, resulting in extremely high temperature due to heat generation from their elements.

In the technique disclosed in Patent Literature 3, it is possible to connect a substrate and an electrode by plating, but it is not clearly disclosed to connect semiconductor elements stacked in a plurality of layers in its stacking direction.

### SUMMARY OF INVENTION

The present invention provides a semiconductor device capable of reducing parasitic inductance and improving heat radiation effect by providing a structure in which, when a switching element and a diode element on a high side and a switching element and a diode element on a low side are formed to have a stacked structure, the switching elements are not adjacent to each other in the stacking direction. Further, the present invention also provides a semiconductor device capable of stabilizing characteristics of connected portions by using a conductive paste or plating when providing the stacked structure with electrical connection.

A semiconductor device according to the present invention includes: a first switching element that is provided on a high side; a first diode element that is connected in parallel to the first switching element; a second switching element that is provide on a low side and connected in series to the first switching element; and a second diode element that is connected in parallel to the second switching element, wherein the first switching element and one of the first diode element and the second diode element are stacked adjacently to each other in a vertical direction of respective electrode surfaces thereof via a conductive electrode, the second switching element and the other of the first diode element and the second diode element that is different from the diode element adjacent to the first switching element are stacked adjacently to each other in a vertical direction of respective electrode surfaces thereof via a conductive electrode, and the first switching element and the second switching element are not adjacent in a vertical direction of respective electrode surfaces thereof.

As described above, in the semiconductor device according to the present invention, it is provided with: a first switching element that is provided on a high side; a first diode element that is connected in parallel to the first switching element; a second switching element that is provide on a low side and connected in series to the first switching element; and a second diode element that is connected in parallel to the second switching element, the first switching element and one of the first diode element and the second diode element are stacked adjacently to each other in a vertical direction of respective electrode surfaces thereof via a conductive electrode, the second switching element and the other of the first diode element and the second diode element that is different from the diode element adjacent to the first switching element are stacked adjacently to each other in a vertical direction of respective electrode surfaces thereof via a conductive electrode, and the first switching element and the second switching element are not adjacent in a vertical direction of respective electrode surfaces thereof, so that a projected area of a path through which current flows in the entire circuit is reduced as compared with the case where all the elements are arranged on a plane, thereby resulting in an advantageous effect that it is possible to substantially reduce parasitic inductance generated in the circuit.

Further, since the first switching element and the second switching element are not adjacent in a vertical direction of respective electrode surfaces thereof, it results in an advantageous effect that it is possible to prevent concentration of heat generation from each switching element to disperse heat generating spots to improve heat radiation effect.

The semiconductor device according to the present invention further includes a heat radiation plate that radiates heat generated in the first switching element and the second switching element, wherein either one of electrode surfaces of the first switching element and/or either one of electrode surfaces of the second switching element is adjacent to the heat radiation plate.

As described above, in the semiconductor device according to the present invention, it is further provided with a heat radiation plate that radiates heat generated in the first switching element and the second switching element, and either one of electrode surfaces of the first switching element and/or either one of electrode surfaces of the second switching element is adjacent to the heat radiation plate, so that it results in an advantageous effect that it is possible to effectively radiate heat generated in the switching elements.

The semiconductor device according to the present invention is such that the first diode element and the second diode element are formed of a silicon carbide (SiC) or gallium nitride (GaN) substrate.

As described above, in the semiconductor device according to the present invention, the first diode element and the second diode element are formed of a silicon carbide (SiC) or gallium nitride (GaN) substrate having a higher thermal conductivity than silicon (Si) which comprises a conventional semiconductor material, so that it results in an advantageous effect that it is possible to effectively radiate heat generated in the first and second switching elements adjacent to the respective diode elements.

The semiconductor device according to the present invention is such that the first switching element, the first diode element, the second switching element, and the second diode element are electrically connected to the conductive electrode by a conductive paste or plating.

As described above, in the semiconductor device according to the present invention, the first switching element, the first diode element, the second switching element, and the second diode element are electrically connected to the conductive electrode by a conductive paste or plating, so that it is possible to perform connection which does not involve melting and solidifying of metal as in the case of solder connection in a manufacturing process, thereby resulting in an advantageous effect that it is possible to stabilize characteristics of the connected portions and realize efficiency with a saving process even in the stacked structure.

The semiconductor device according to the present invention is such that a melting point T of the conductive paste, a material of the plating, and a metal of the electrode surface satisfies T/2>500 (K).

As described above, in the semiconductor device according to the present invention, a melting point T of the conductive paste, a material of the plating, and a metal of the electrode surface satisfies T/2>500 (K), so that it results in an advantageous effect that it is possible to reduce damage to the device even at a high temperature to use the device for a long time.

### BRIEF DESCRIPTION OF DRAWINGS

FIG. 1 is a circuit diagram of a semiconductor device according to a first embodiment.

FIGS. 2A and 2B are diagrams showing a mounting structure of a general power supply circuit, where FIG. 2A is a cross-sectional view in arrow A, and FIG. 2B is a top view.

FIGS. 3A to 3C are first schematic diagrams each showing a stacked structure of switching elements and diodes of the semiconductor device according to the first embodiment.

FIG. 4 is a second schematic diagram showing a stacked structure of switching elements and diodes of the semiconductor device according to the first embodiment.

FIGS. 5A to 5C are third schematic diagrams each showing a stacked structure of switching elements and diodes of the semiconductor device according to the first embodiment.

FIGS. 6A and 6B are fourth schematic diagrams each showing a stacked structure of switching elements and diodes of the semiconductor device according to the first embodiment.

FIG. 7 is a fifth schematic diagram showing a stacked structure of switching elements and diodes of the semiconductor device according to the first embodiment.

FIGS. 8A and 8B are sixth schematic diagrams each showing a stacked structure of switching elements and diodes of the semiconductor device according to the first embodiment.

FIGS. 9A and 9B are other schematic diagrams each showing a stacked structure of switching elements and diodes of the semiconductor device according to the first embodiment.

FIGS. 10A and 10B are diagrams showing a connection structure in a case where semiconductor elements in the semiconductor device according to the first embodiment are connected via a lead frame, where FIG. 10A is a top view and FIG. 10B is a cross-sectional view taken along the line B-B of FIG. 10A.

FIGS. 11A and 11B are first enlarged views in a case where a first connection surface and a second connection surface in an electrode connection structure of the semiconductor device according to the first embodiment are plated.

FIGS. 12A and 12B are second enlarged views in a case where a first connection surface and a second connection surface in an electrode connection structure of the semiconductor device according to the first embodiment are plated.

FIG. 13 a perspective view showing a shape of a lead in an electrode connection structure of the semiconductor device according to the first embodiment.

FIGS. 14A to 14C are diagrams showing a connection structure of a lead frame and a semiconductor element in an electrode connection structure of the semiconductor device according to the first embodiment, where FIG. 14A is a side view, FIG. 14B is a front view, and FIG. 14C is a bottom view.

FIGS. 15A and 15B are diagrams showing configurations when the shape of the lead 11 shown in FIG. 13 is improved.

FIGS. 16A and 16B are diagrams showing modified examples of the lead shown in FIGS. 15A and 15B.

FIG. 17 is a front view showing an electrode connection structure of the semiconductor device according to the first embodiment.

FIGS. 18A and 18B are views showing application examples of the electrode connection structure shown in FIG. 17.

FIG. 19A is a diagram showing a structure of a semiconductor device according to the present invention in a case where the semiconductor device is sterically mounted, and FIG. 19B is a diagram showing a structure of a semiconductor device according to the present invention in a case where the semiconductor device is planarly mounted.

FIG. 20 is a schematic diagram showing a chip stack cross-section in a case where a MOSFET and a diode are mounted on a copper lead frame by plating joining.

FIG. 21 is a diagram showing an example of a plating connection structure using a SiC chip and a ceramic substrate.

FIG. 22 is a view showing an observation case (optical microscope photograph) of a cross-section of a joined portion by Ni plating between electrodes using a ball.

FIG. 23 is a schematic diagram explaining an example of a three-dimensional joining structure using a ceramic substrate.

### DESCRIPTION OF EMBODIMENTS

Hereinafter, embodiments of the present invention will be described. The same reference numerals are given to the same elements throughout the entire embodiments.

### First Embodiment

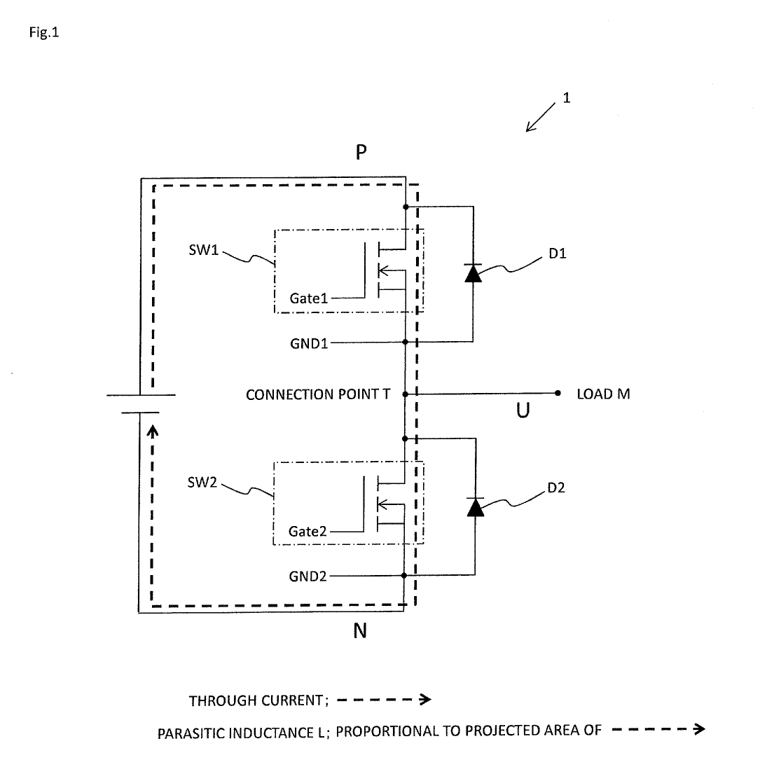

A semiconductor device according to the present embodiment will be described with reference to FIGS. 1 to 18B. The semiconductor device according to the present embodiment is an in-vehicle inverter, which uses switching elements such as a power metal-oxide semiconductor field-effect transistor (MOSFET), including a high-side switching element and a low-side switching element, and further including diodes corresponding to the respective switching elements, for example. In the present embodiment, parasitic inductance L is reduced by making a stacked structure in which the respective elements are stacked, and at the same time, heat radiation effect is improved by preventing the switching elements from being stacked adjacently to each other.

FIG. 1 is a circuit diagram of a semiconductor device according to the present embodiment. In FIG. 1, a switching power supply circuit 1 converts a direct current into an alternating current and supplies the alternating current to a load. The direct current supplied to the switching power supply circuit 1 is converted into the alternating current by complementary switching of the switching elements. A high-side switching element SW1 and a low-side switching element SW2 are connected in series, and electric power is supplied from a connection point T thereof to a load M such as a motor, for example. Diodes D1 and D2 are connected to the switching elements SW1 and SW2, respectively, in reversely parallel to the respective switching elements SW1 and SW2 such that the switching elements SW1 and SW2 are not destroyed by counter electromotive force.

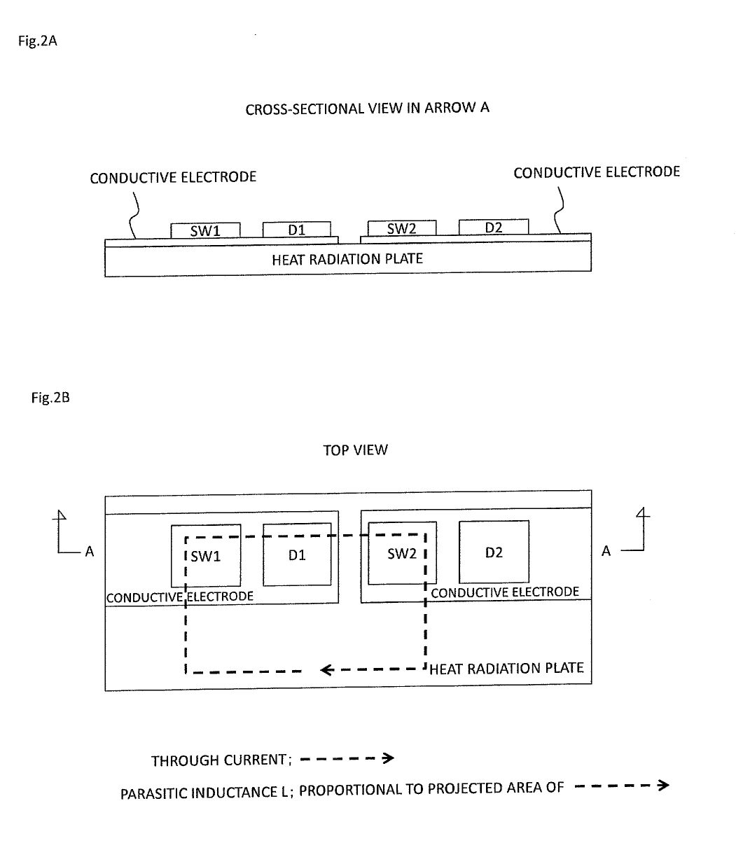

In the switching power supply circuit 1 of FIG. 1, a through current flows through a current loop from an input terminal to an output terminal due to parasitic inductance L of this circuit at the time of switching transition of the switching elements SW1 and SW2, resulting in a large loss. This parasitic inductance L is proportional to a projected area of the current loop of the switching elements SW1 and SW2 as shown in FIG. 1, so that it is possible to reduce the parasitic inductance L by making the current loop smaller to eliminate the loss. In the case of mounting the switching power supply circuit 1 shown in FIG. 1, the switching power supply circuit 1 generally has a planar structure as shown in FIGS. 2A and 2B due to restrictions on mounting and the like in view of wiring connection by wire bonding and the aspect of cost, so that the projected area of the current loop from the input terminal through the switching elements to the output terminal cannot help but be increased, resulting in an increase in a switching loss. There is also known a technique of stacking chips at the time of connection by wire bonding, but it causes problems such as influence of heat by soldering at the time of stacking, instability of stacked arrangement due to melting of metal at the time of soldering, and the like.

In the semiconductor device according to the present embodiment, in order to reduce the projected area of the current loop of the switching elements SW1 and SW2, such a structure is made that the switching elements SW1 and SW2 and the diodes D1 and D2 are stacked, and at the same time, heat radiation effect of the stacked switching elements SW1 and SW2 is also improved, while making the device compact.

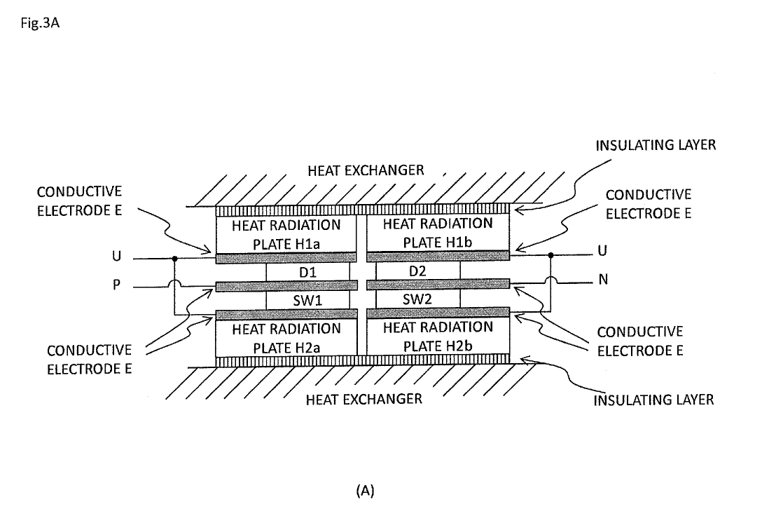

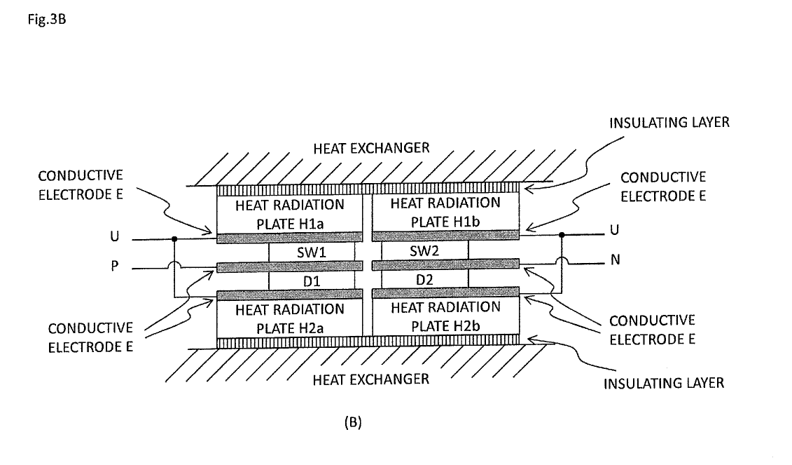

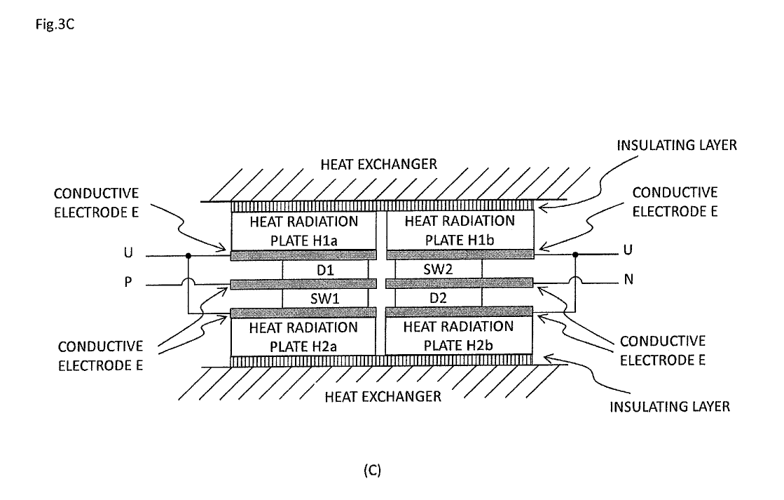

FIGS. 3A to 3C are first schematic diagrams each showing a stacked structure of switching elements and diodes of the semiconductor device according to the present embodiment. In FIGS. 3A to 3C, it is desirable that at least the diodes D1 and D2 are formed of semiconductors such as silicon carbide (SiC), gallium nitride (GaN), or the like having high heat radiation properties. In this case, a stacked structure of the switching element SW1 and the diode D1 on the high side and a stacked structure of the switching element SW2 and the diode D2 on the low side are arranged in parallel in a horizontal direction of the respective electrode surfaces thereof, and the elements are electrically connected via conductive electrodes E. This arrangement enables the current loop to be smaller and the loss to be suppressed.

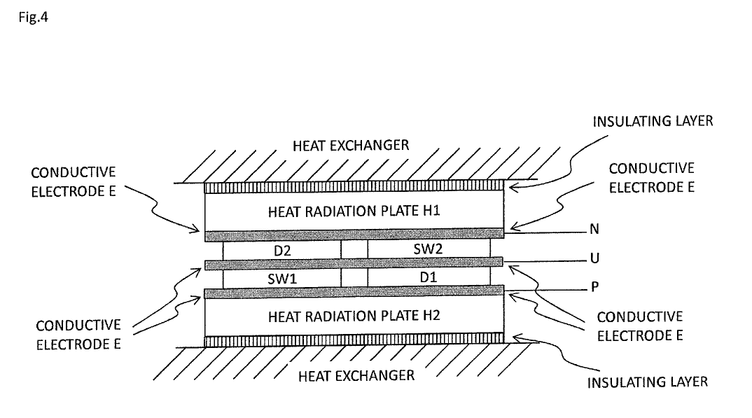

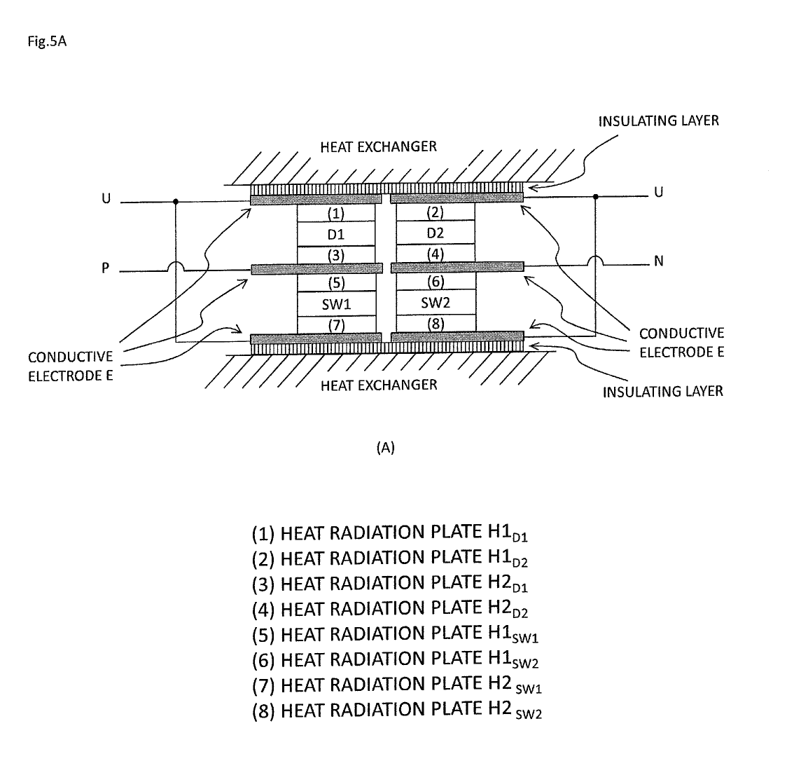

In addition, a stacked structure of the switching element SW1 on the high side and the diode D2 on the low side and a stacked structure of the switching element SW2 on the low side and the diode D1 on the high side may be arranged in parallel in the horizontal direction of the respective electrode surfaces thereof, as shown in FIG. 4. In this case, the same effect as described above can be obtained as well.

Further, in FIGS. 3A to 3C and FIG. 4, heat radiation plates H1 (H1a, H1b) and H2 (H2a, H2b) that radiate heat generated in the respective switching elements SW1, SW2 are provided on the uppermost and lowermost surfaces of the respective stacked structures, and the switching element SW1 and the switching element SW2 are stacked so as not to be adjacent in a direction perpendicular to their electrode surfaces. That is, in a case where the switching element SW1 and the switching element SW2 are stacked adjacently to each other in the direction perpendicular to their electrode surfaces, heat generated in the respective switching elements SW1 and SW2 is concentrated on the adjacent surfaces (the conductive electrodes E sandwiched between the switching elements SW1 and SW2) to become a high temperature, which may cause destruction of the device or the like.

In order to prevent this, the stacked structure is formed such that the diodes D1 and D2 formed of SiC, for example, having high heat radiation properties, or the heat radiation plates H1 and H2 are necessarily adjacent to the electrode surfaces of the switching elements SW1 and SW2, as shown in FIGS. 3A-3C and FIG. 4. An insulating layer is also formed on the outside of each of the heat radiation plates H1 and H2 (the upper surface side of the heat radiation plate H1 and the lower surface side of the heat radiation plate H2), and a heat exchanger such as a radiator or a heat sink is disposed further outside each insulating layer. With such a configuration, it is made possible to radiate heat from both electrode surfaces on the front surface and the rear surface of the respective switching elements SW1 and SW2, and to remarkably improve heat radiation effect.

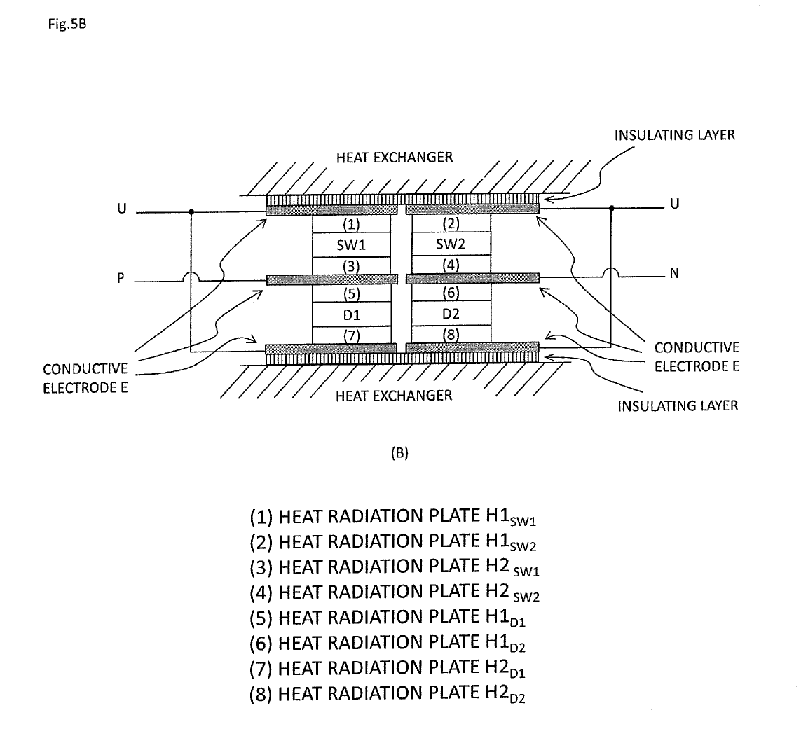

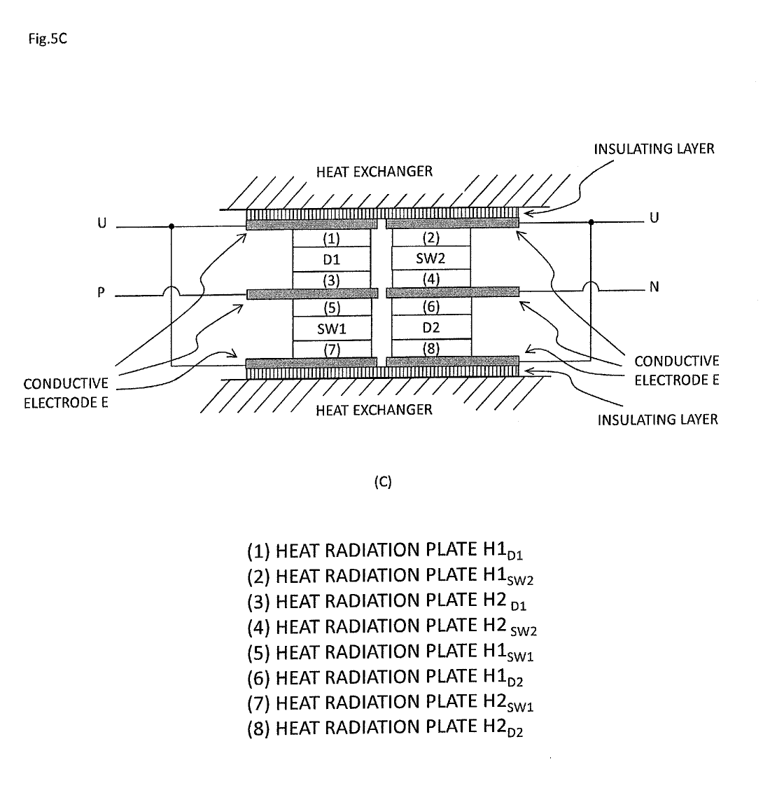

FIGS. 5A to 5C are third schematic diagrams each showing a stacked structure of switching elements and diodes of the semiconductor device according to the present embodiment. FIGS. 5A to 5C show stacked structures in a case where the heat radiation plates H1 and H2 are provided for each element in the stacked structures shown in FIGS. 3A to 3C, where the structures of FIGS. 5A to 5C correspond to the structures of FIGS. 3A to 3C, respectively. In FIGS. 5A to 5C, there are provided none of the heat radiation plates H1 and H2 shown in FIGS. 3A to 3C, and instead, heat radiation plates H1_{SW1}, H2_{SW1}, H1_{D1}, H2_{D1}, H1_{SW2}, H2_{SW2}, H1_{D2}, and H2_{D2} are provided such that these heat radiation plates are each adjacent to both sides of the front surface side and the rear surface side (corresponding to the upper surface side and the lower surface side in FIGS. 5A to 5C) of each element. With such a configuration, it is made possible to improve heat radiation for each element. Note that in the stacked structure shown in FIG. 4, it is also possible to provide the heat radiation plates H1_{SW1}, H2_{SW1}, H1_{D1}, H2_{D1}, H1_{SW2}, H2_{SW2}, H1_{D2}, and H2_{D2} in the same manner.

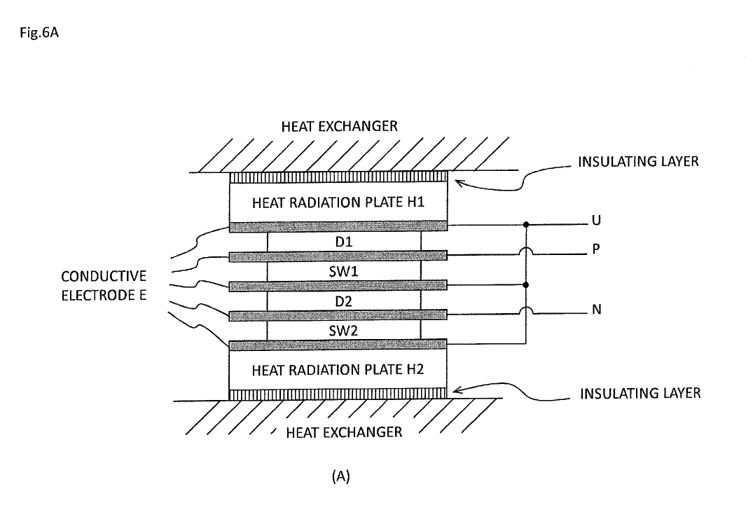

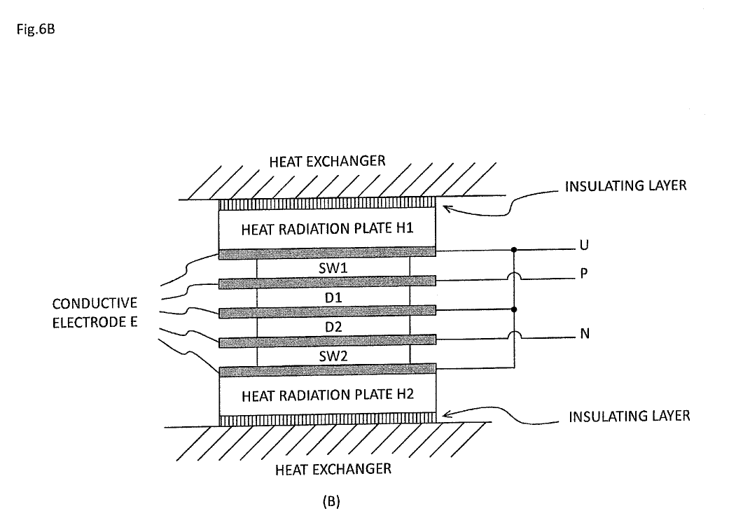

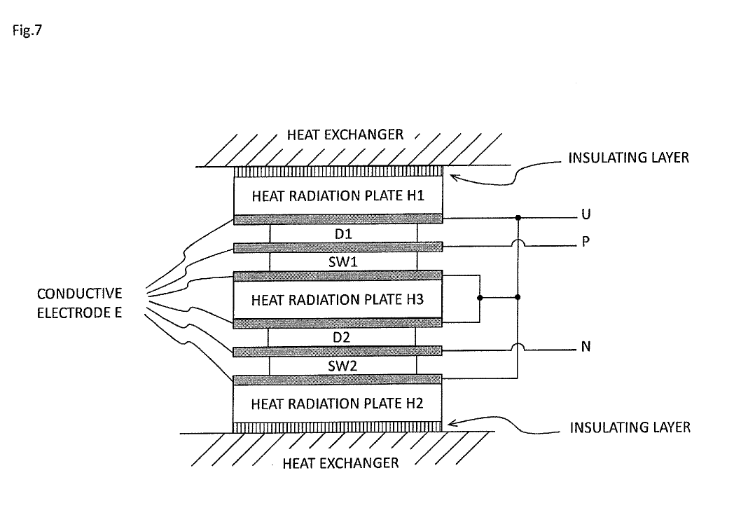

FIGS. 6A-6B and FIG. 7 are fourth and fifth schematic diagrams, respectively, each showing a stacked structure of switching elements and diodes of the semiconductor device according to the present embodiment. In FIGS. 6A-6B and FIG. 7, at least the diodes D1 and D2 are formed of SiC having high heat radiation properties as is the case in FIGS. 3A to 5C. A stacked structure of the switching element SW1 and the diode D1 on the high side and a stacked structure of the switching element SW2 and the diode D2 on the low side are stacked in a vertical direction of the respective electrode surfaces thereof. This arrangement enables the current loop to made smaller than in the case of FIGS. 3A to 5C and the loss to be more suppressed.

Further, as is the case in FIGS. 3A-3C and FIG. 4, the switching element SW1 and the switching element SW2 are stacked so as not to be adjacent in a direction perpendicular to their electrode surfaces, heat radiation plates H1 and H2 that radiate heat generated in the respective switching elements SW1 and SW2 are provide, insulating layers are disposed outside the heat radiation plates H1 and H2, and heat exchangers are further disposed outside the insulating layers. That is, the stacked structure is formed such that the diodes D1 and D2 formed of SiC, for example, having high heat radiation properties, or the heat radiation plates H1 and H2 are necessarily adjacent to the electrode surfaces of the switching elements SW1 and SW2, so that it is made possible to radiate heat from both electrode surfaces on the front surface and the rear surface of the respective switching elements SW1 and SW2, and to remarkably improve heat radiation effect.

Note that in the case where the switching element SW1 or SW2 is structured not to be adjacent to any one of the heat radiation plates H1 and H2 on either of the electrode surfaces thereof as shown in FIG. 6A (in the case of FIG. 6A, the switching element SW1 is structured not to be adjacent to any of the heat radiation plates H1 and H2), heat is diffused by the diodes D1 and D2, but it is difficult to radiate heat toward outside. Therefore, in such a case, it is desirable to provide a heat radiation plate H3 between the switching element SW1 and the diode D2 as shown in FIG. 7. By doing so, it is possible to radiate heat generated in the switching element SW1 to the outside of the semiconductor device by the heat radiation plate H3, while diffusing the heat by the diode D2.

Further, the term “adjacent in a vertical direction” in the present embodiment refers to a structure in which two elements arranged in a vertical direction are directly connected via an electrode, a wiring substrate, a heat radiation plate, or the like. Therefore, the case where another element is interposed between the two elements arranged in the vertical direction is not referred to being “adjacent.”

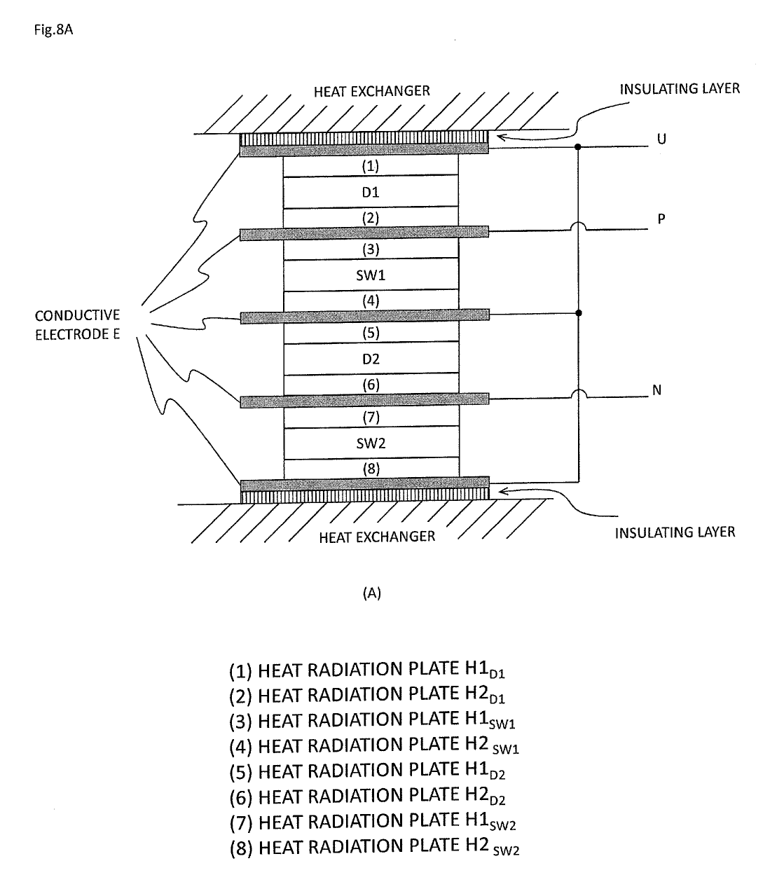

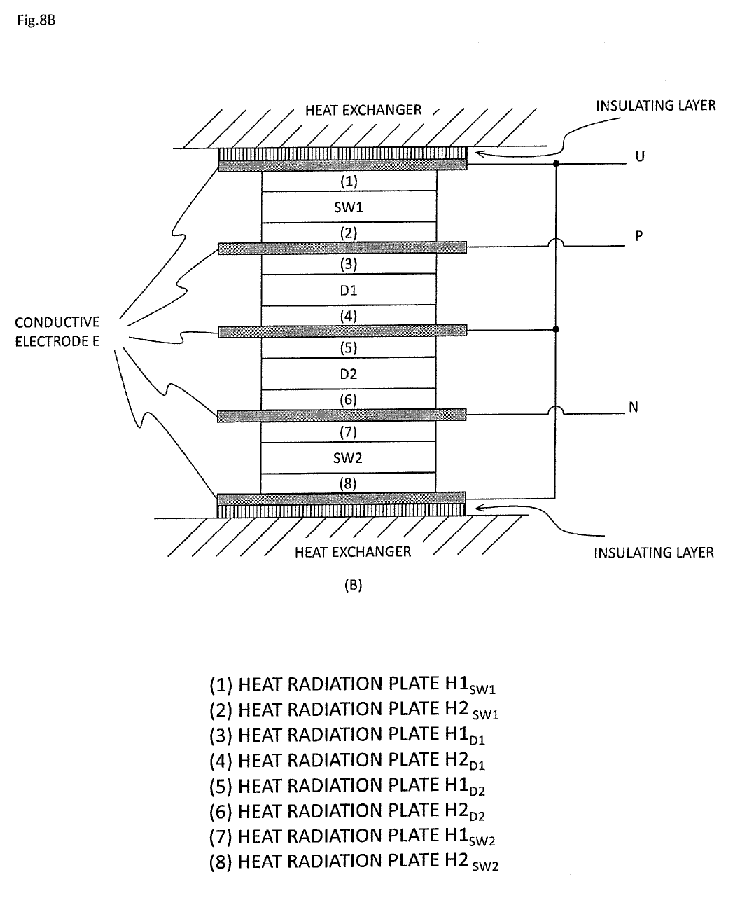

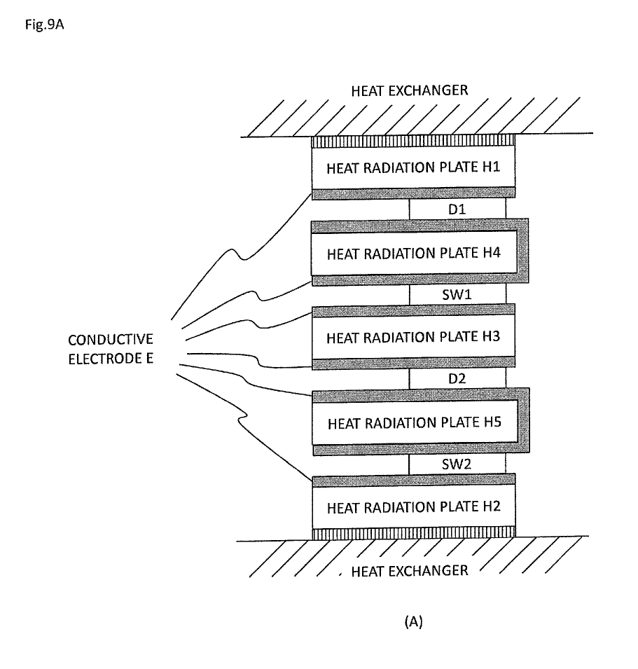

FIGS. 8A and 8B are sixth schematic diagrams each showing a stacked structure of switching elements and diodes of the semiconductor device according to the present embodiment. FIGS. 8A and 8B show stacked structures in a case where the heat radiation plates H1 and H2 are provided for each element in the stacked structures shown in FIGS. 6A and 6B, as is the case in FIGS. 5A to 5C, where the structures of FIGS. 8A and 8B correspond to the structures of FIGS. 6A and 6B, respectively. Note that the structure of FIG. 7 corresponds to the structure of FIG. 8A. In FIGS. 8A and 8B, there are provided none of the heat radiation plates H1 and H2 shown in FIGS. 6A and 6B, and instead, heat radiation plates H1_{SW1}, H2_{SW1}, H1_{D1}, H2_{D1}, H1_{SW2}, H2_{SW2}, H1_{D2}, and H2_{D2} are provided such that these heat radiation plates are each adjacent to both sides of the front surface side and the rear surface side (corresponding to the upper surface side and the lower surface side in FIGS. 8A and 8B) of each element. With such a configuration, it is made possible to improve heat radiation for each element.

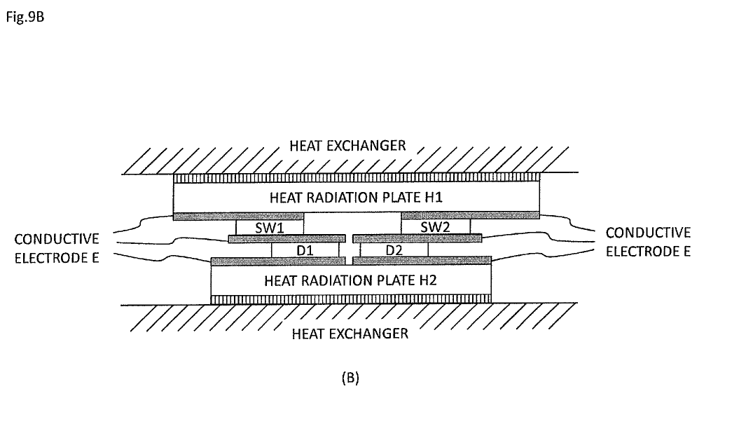

Other than the above structures, additional stacked structures may be formed with structures as shown in FIGS. 9A and 9B, for example. In FIG. 9A, heat radiation plates are inserted between every layers in a stacked structure of the switching elements SW1 and SW2 and the diodes D1 and D2, so that it is possible to remarkably improve heat radiation effect. In FIG. 9B, axes of a stacked structure in a vertical direction are purposely deviated, so that it is possible to facilitate circulation of a plating solution in the plating treatment described below and to make a heat radiation plate(s) larger to improve heat radiation effect.

As described above, the switching elements SW1, SW2 and the diodes D1, D2 are formed to have a stacked structure, and the switching elements SW1 and SW2 are not adjacent in the stacking direction, so that it is possible to make the current loop smaller to reduce the parasitic inductance and it is also possible to radiate heat from both electrode surfaces on the front surface and the rear surface of the respective switching elements SW1 and SW2 to remarkably improve heat radiation effect.

Next, a connection structure and a method for forming the connection structure in a case where the above-described stacked structure is formed by plating will be described. In the present embodiment, plating connection using nickel (Ni) having a very high melting point and good corrosion resistance, and connection by a conductive paste can be applied, for example, so that a connection that can withstand high temperature environments can be realized. In the following cases, plating connection will be explained.

As described above, the semiconductor elements (between the switching elements SW1, SW2 and the diodes D1, D2) are electrically connected via the conductive electrodes E. That is, the electrode on the front surface side of one semiconductor element and the electrode on the rear surface side of the other semiconductor element are joined by plating via the conductive electrode E, whereby the respective semiconductor elements are electrically connected. A ball bump or a lead frame is used as the conductive electrode E, for example. Since a specific method of plating treatment is a well-known technique (see US 2016/0225730 A1, for example), detailed description thereof will be omitted. Hereinafter, an electrode connection structure will be described in detail.

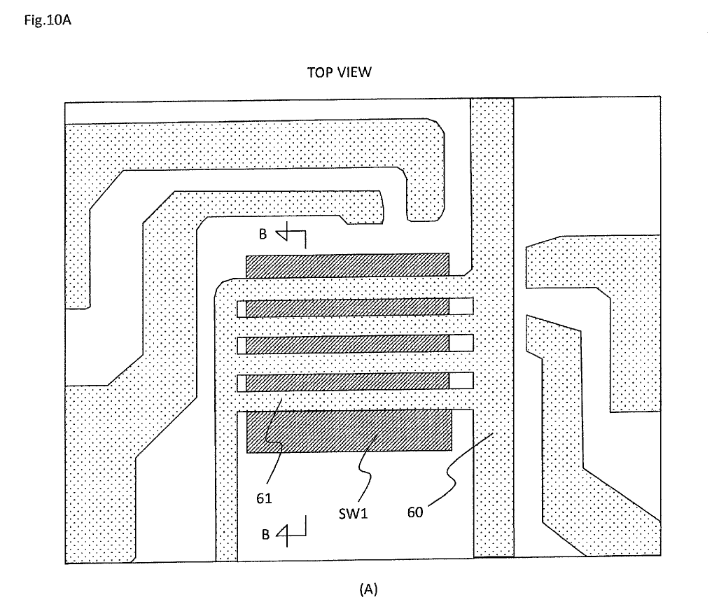

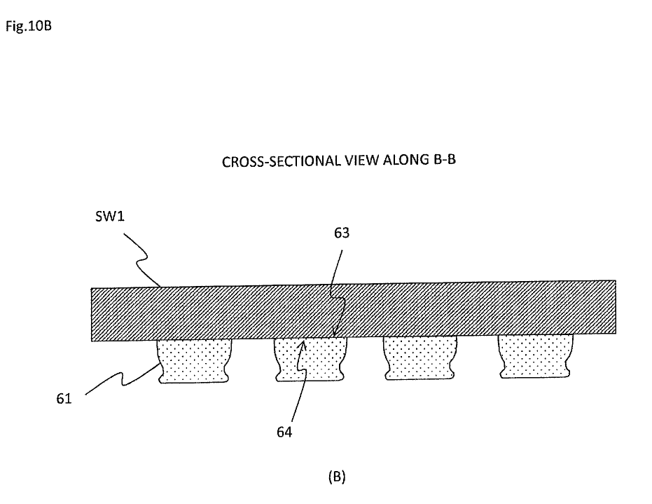

FIGS. 10A and 10B are diagrams showing a connection structure in a case where semiconductor elements are connected via a lead frame. FIG. 10A is a top view in a case where a semiconductor element (the switching element SW1, SW2 or the diode D1, D2) and a lead frame are connected to each other, and FIG. 10B is a sectional side view in the case where the semiconductor element and the lead frame are connected to each other. As shown in FIGS. 10A and 10B, a lead frame 60 has a plurality of elongated leads 61 arranged in parallel like a ladder and a longitudinal side surface of each lead 61 in the lead frame 60 is connected to an electrode of a semiconductor element (in FIGS. 10A and 10B, the switching element SW1 is shown as an example) by plating. An electrode surface of the switching element SW1, which is connected in direct contact with the lead frame 60, is referred to as a first connection surface 63, and the longitudinal side surface of the lead 61, which is in contact with the first connection surface 63, is referred to as a second connection surface 64. The switching element SW1 and the lead frame 60 are electrically connected to each other by joining the first connection surface 63 and the second connection surface 64 together by plating between both connection surfaces 63 and 64.

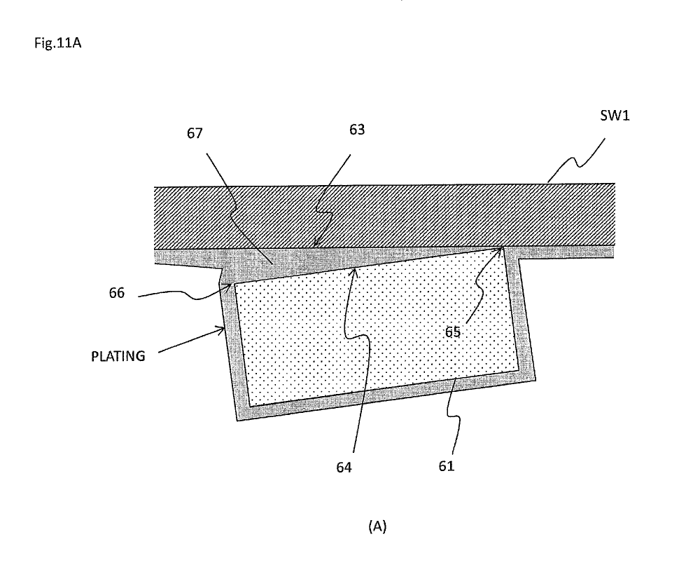

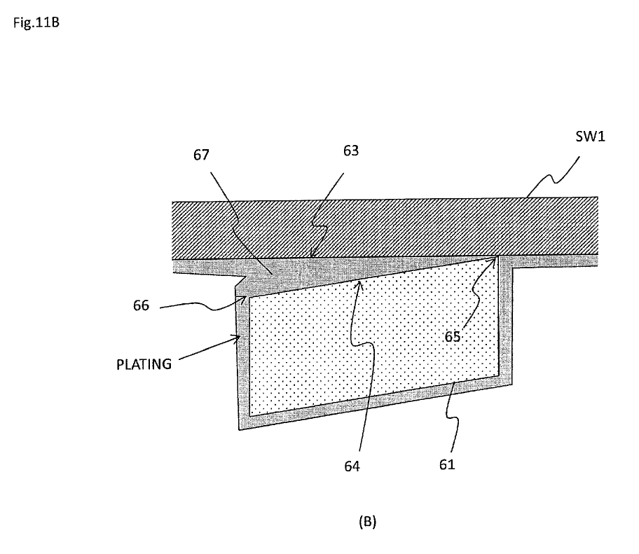

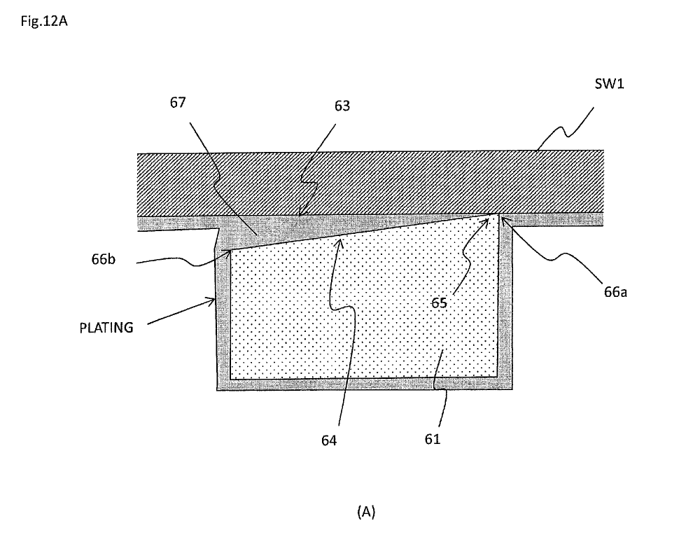

FIGS. 11A and 11B are first enlarged views in a case where the first connection surface and the second connection surface in the electrode connection structure of the semiconductor device according to the present embodiment are plated. When the first connection surface 63 and the second connection surface 64 are plated in a state Where both connection surfaces 63 and 64 are in close contact with each other on a plane-to-plane basis, there may be a case where a plating solution is not sufficiently circulated between the first connection surface 63 and the second connection surface 64 and a defect such as a void is formed, which leads to deterioration of quality. Therefore, for the purpose of sufficiently circulating the plating solution between the first connection surface 63 and the second connection surface 64, an edge portion 65 is provided on the second connection surface 64, and a gap 67 is formed such that a distance between the first connection surface 63 and the second connection surface 64 increases continuously, in a state where the edge portion 65 is in contact with the first connection surface 63, from the edge portion 65 toward an outer portion 66 of the second connection surface 64 (an end of the second connection surface). With the formation of the gap 67, it is possible to sufficiently circulate the plating solution between the first connection surface 63 and the second connection surface 64, and it is possible to fill the gap 67 gradually from the periphery of the edge portion 65 by plating, thereby enabling a wide area of the gap 67 to be filled with plating.

Note that FIG. 11A shows a case where a cross section of the lead 61 is a rectangle, and FIG. 11B shows a case where the cross section of the lead 61 is a parallelogram. Other than those, the cross-sectional shape of the lead 61 may be in the shape of a polygon such as a square, a rhombus, or a trapezoid. In terms of manufacturing, it is preferable to be rectangular as shown in FIG. 11A or square in shape to reduce time and effort of the work. In a case where the edge portion 65 is formed on a part of an end of the second connection surface 64 as shown in FIGS. 11A and 11B, the gap 67 is formed such that the distance between the respective connection surfaces continuously increases toward the outer portion 66 except for a portion where the edge portion 65 is formed.

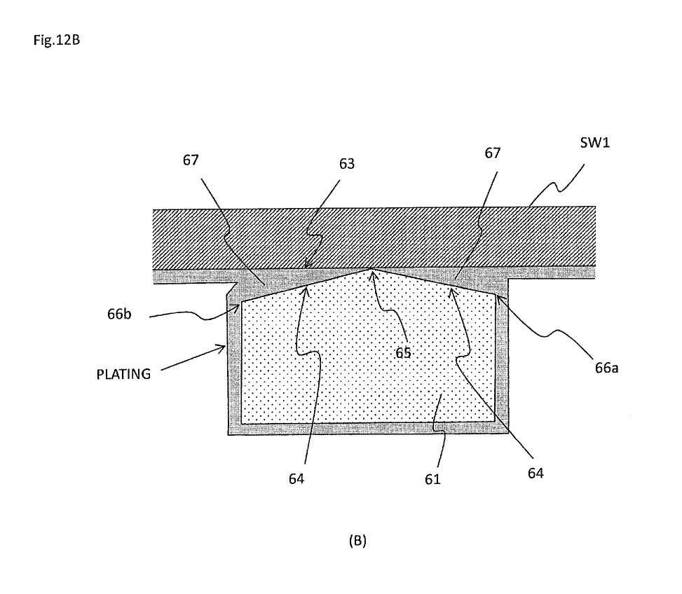

FIGS. 12A and 12B are second enlarged views in a case where the first connection surface and the second connection surface are plated. FIG. 12A shows a structural example in which the edge portion 65 is provided at an outer portion 66a of one end of the second connection surface 64 and the lead 61 is reduced in thickness toward an outer portion 66b on the other end of the second connection surface 64, resulting in that the gap 67 is formed such that the distance between the first connection surface 63 and the second connection surface 64 continuously increases from the edge portion 65 toward the outer portion 66b. This reduction in thickness can be performed not only by press working but also by etching processing or cutting working.

FIG. 12B shows another structural example in which the edge portion 65 is provided at a center portion along a longitudinal direction on the second connection surface 64 and the lead 61 is reduced in thickness toward the outer portions 66a and 66b at both ends, resulting in that the gap 67 is formed such that the distance between the first connection surface 63 and the second connection surface 64 continuously increases from the edge portion 65 toward the outer portions 66a and 66b. This reduction in thickness can be performed not only by press working but also by etching processing or cutting working.

As shown in FIGS. 12A and 12B, the thickness reduction of the second connection surface 64 of the lead 61 from the edge portion 65 toward the outer portion 66 of the lead 61 can make the gap 67. By allowing the plating solution to sufficiently flow through the gap 67, it is possible to connect the first connection surface 63 and the second connection surface 64 by plating without causing defects such as voids, and it is possible to widely fill the region, where the first connection surface 63 and the second connection surface 64 are opposed, with plating.

In the above, the connection structure between the lead frame 60 and the electrode of the semiconductor element has been described. However, the same electrode connection structure technology can be applied to the connection between the lead frame 60 and a substrate electrode. Further, the distance between the first connection surface 63 and the second connection surface 64 that continuously increases from the edge portion 65 toward the outer portion 66 of the lead 61 can be arbitrarily set according to the rate of plating progression. For example, it is set to such a distance (=edge angle) that the gap 67 is gradually filled with plating from the edge portion 65.

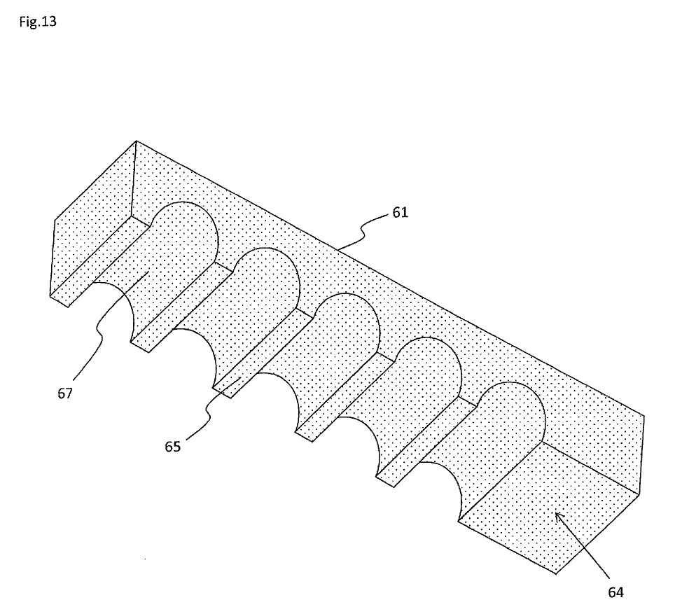

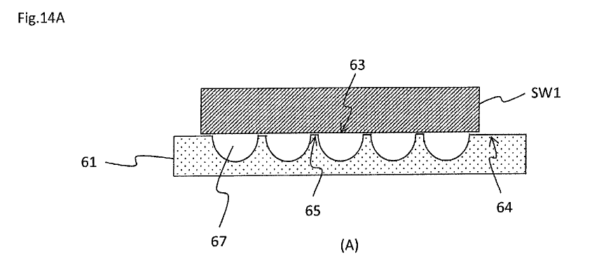

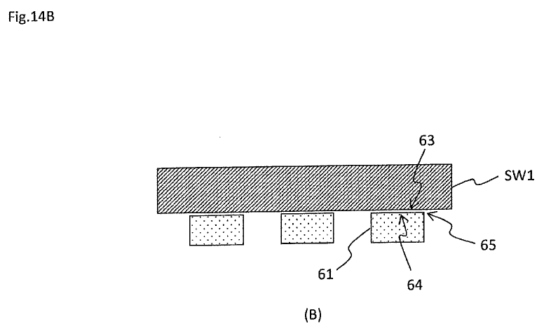

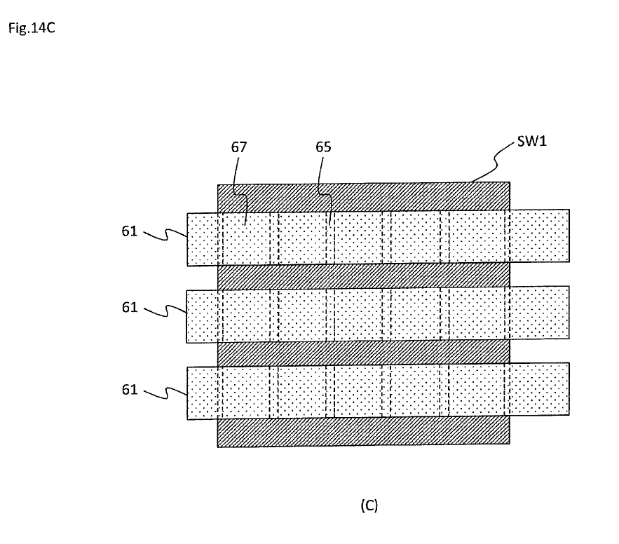

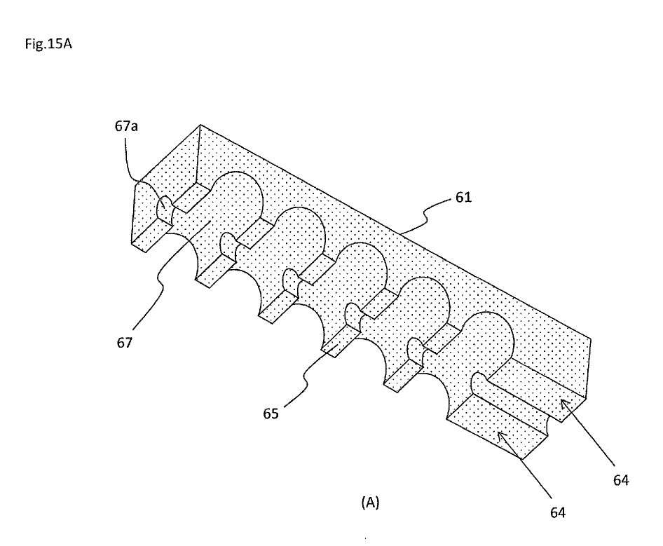

In addition, other electrode connection structures will be described below. FIG. 13 is a perspective view showing a shape of a lead in the electrode connection structure of the semiconductor device according to the present embodiment, and FIGS. 14A to 14C are diagrams showing a connection structure of a lead frame and a semiconductor element in the electrode connection structure of the semiconductor device according to the present embodiment. As shown in FIG. 13, a plurality of narrow transverse edge portions 65 are formed on the second connection surface 64 of the lead 61 in a transverse direction thereof, and a transverse concave groove-like gap 67 is formed between each pair of adjacent transverse edge portions 65, wherein the transverse gap 67 penetrates in the transverse direction of the second connection surface 64.

Then, as shown in FIGS. 14A to 14C, plating treatment is performed in a state where the edge portion 65 of the lead 61 is in contact with the switching element SW1. FIG. 14A is a side view showing the connection structure of the lead frame and the switching element SW1, FIG. 14B is a front view showing the connection structure of the lead frame and the semiconductor element SW1, and FIG. 14C is a bottom view showing the connection structure of lead frame and the semiconductor element SW1. The lead 61 has the transverse concave groove-like gap 67 formed between each pair of adjacent transverse edge portions 65 as shown in FIG. 13, so that a plating solution is sufficiently circulated around the edge portions 65, thereby resulting in that it is possible to perform high-quality plating treatment around the edge portions 65 as described above. Further, forming the plurality of transverse gaps 67 between each pair of adjacent transverse edge portions 65 makes it possible to disperse the stress applied in the longitudinal direction and prevent breakage and the like of the lead 61.

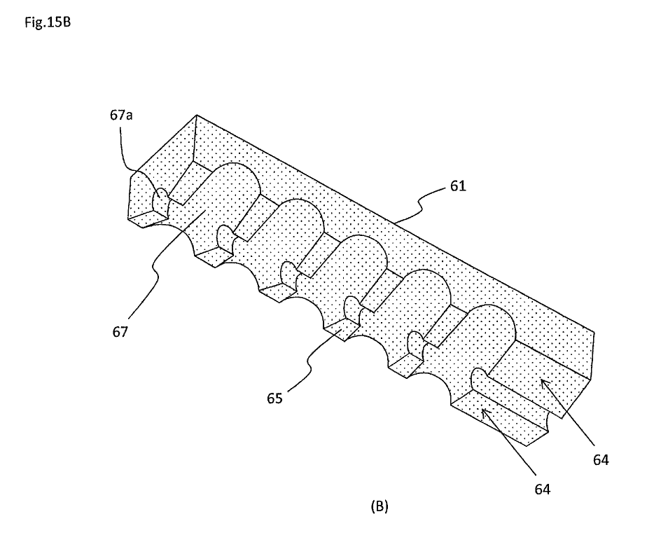

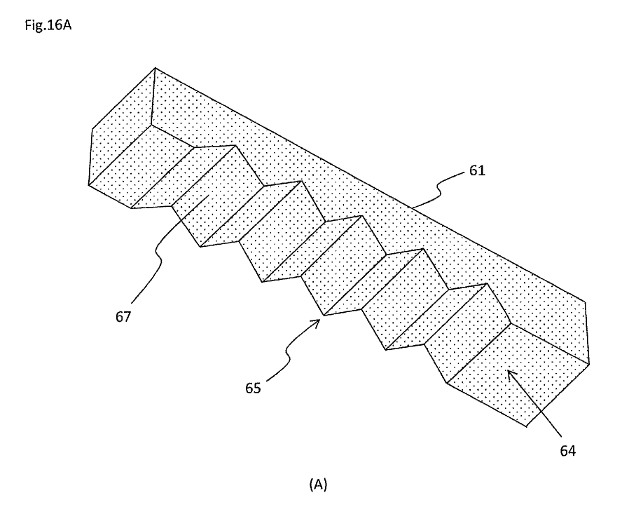

A further improvement of the shape of the lead 61 shown in FIG. 13 is shown in FIGS. 15A and 15B. FIG. 15A shows such a structure that a longitudinal concave groove-like gap 67a that is discontinuous in a longitudinal direction is further formed in the shape of the lead 61 shown in FIG. 13, and FIG. 15B shows such a structure that the edge portions 65 formed in the transverse direction of the lead 61 is further formed into a chevron shape. Forming notches in parts of the edge portions 65 to form the discontinuous longitudinal concave groove-like gap 67a in the longitudinal direction as shown in FIG. 15A makes it possible to disperse the stress applied in the transverse direction and to prevent breakage and the like of the lead 61.

FIG. 15B shows such a structure that the edge portion 65 in FIG. 15A is processed to have a chevron shape when viewed from the longitudinal direction of the lead 61. This processing makes it possible to disperse the stress applied to the lead 61 and to prevent breakage and the like of the lead 61 as described above, and also makes it possible to more effectively circulate the plating solution to perform extremely high-quality plating treatment. Note that in FIG. 15B, the discontinuous longitudinal concave groove-like gap 67a in the longitudinal direction may be omitted.

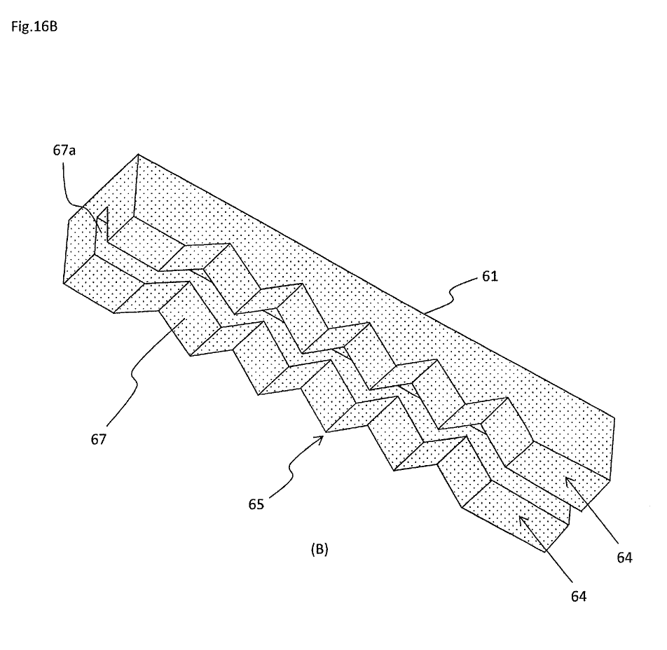

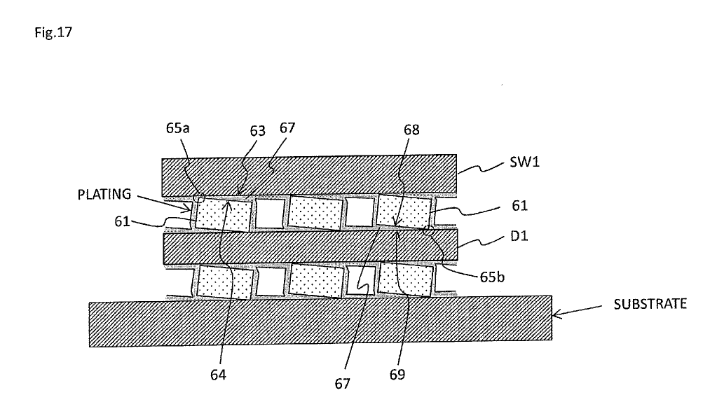

FIGS. 16A and 16B show modified examples of the lead shown in FIGS. 15A and 15B. In the case of FIGS. 16A and 16B, a plurality of edge portions 65 that are narrower than those in the case of FIGS. 15A and 15B are formed in the transverse direction. Further, the transverse concave groove-like gap 67 penetrating in the transverse direction is not in the shape of an R but in the shape of a concave groove having an acute angle (see FIG. 16A), Even in such a shape of the lead 61 as well, forming notches in parts of the edge portions 65 to form continuous longitudinal concave groove-like gap 67a in the longitudinal direction as is the case in FIG. 15A makes it possible to disperse the stress applied in the transverse direction and to prevent breakage and the like of the lead 11 (see FIG. 16B), Furthermore, processing the edge portion 65 to have a chevron shape when viewed from the longitudinal direction of the lead 61 as is the case in FIG. 6B makes it possible to more effectively circulate the plating solution to perform extremely high-quality plating treatment.

Next, a stacked structure of the electrode connection structure will be described below. FIG. 17 is a front view showing a stacked structure of the semiconductor device according to the present embodiment. As shown in FIG. 17, an edge portion 65a is provided on the second connection surface 64 that is an upper surface side of the lead 61, and an edge portion 65b is provided on the third connection surface 68 that is a lower surface side of the lead 61. With respect to plating treatment between the first connection surface 63 and the second connection surface 64, high-quality plated connection can be made as described above. Similarly, the connection between the third connection surface 68 and a fourth connection surface 69 that is a semiconductor element (here, the diode D1 is shown as an example) electrode surface connected to the third connection surface 68 also allows for high-quality plated connection.

That is, a gap 67 is formed such that a distance between the fourth connection surface 69 and the third connection surface 68 increases continuously, in a state where the edge portion 65b of the third connection surface 68 is in contact with the fourth connection surface 69, from the edge portion 65b toward an outer portion 66 of the third connection surface 68, so that a plating solution can be sufficiently circulated in the gap 67, thereby allowing for high-quality plated connection without defects such as voids.

As described above, performing the above plating connection with the semiconductor elements (the switching element SW1 and the diode D1) on both front and back surfaces in the longitudinal side surface of the lead 61 makes it possible to stack the semiconductor elements in multiple layers, thereby resulting in that it is possible to realize a high-quality plated connection and to remarkably improve work efficiency by simplifying stacking process of the semiconductor elements.

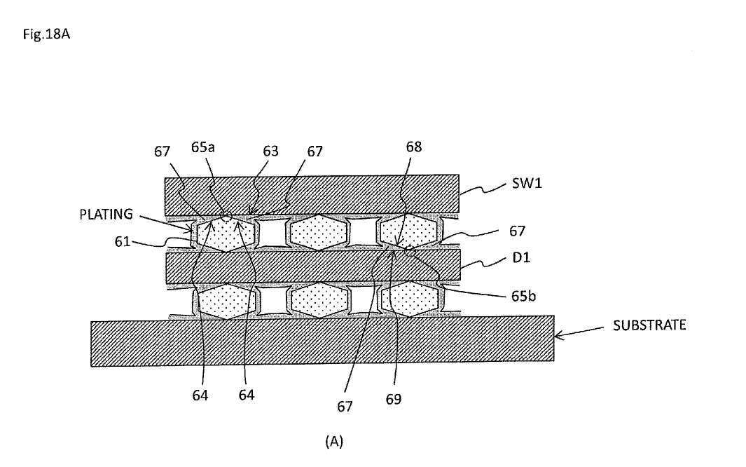

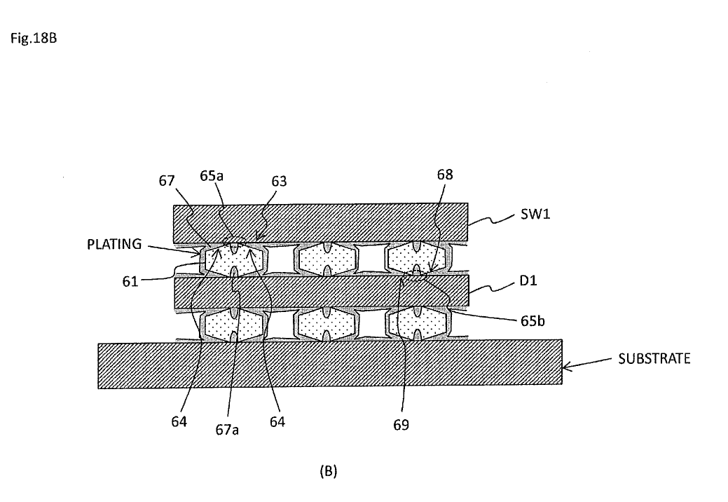

In addition, processing both front and back surfaces of the longitudinal side surface of the lead 61 makes it possible to stack the semiconductor elements in multiple layers using the electrode connection structure as shown in FIGS. 18A and 189.

Further, it is desirable to perform the above plating connection treatment by plating with a metal or an alloy having a melting point satisfying T/2>500 (K), and in particular, the metal or the alloy is desirably nickel (Ni) or a nickel (Ni) alloy, copper (Cu) or a Cu alloy, or silver (Ag) or an Ag alloy. This allows high quality to be maintained without damaging the connected portion even when it is used at a high temperature of approximately 300° C. or higher, for example. Further, using Ni or a Ni alloy, Cu or a Cu alloy, or Ag or an Ag alloy allows for plating treatment at a temperature of 100° C. or lower, resulting in that it is possible to eliminate damages to the semiconductor element, the substrate, the lead frame and the like due to stress and heat at the time of joining, thereby maintaining high quality. In addition, it is also desirable that a melting point of a metal used as the conductive paste, the semiconductor element electrode, and/or the wiring satisfies T/2>500 (K).

Further, in a case where the element electrode surface comprises an aluminum (Al) or Al alloy electrode, it is preferable to form any of metal having a melting point satisfying T/2>500 (K) and also having excellent adhesion to Al, such as chromium (Cr), nickel (Ni), palladium (Pd), or titanium (Ti), for example, or an alloy thereof hereof, on the electrode surface. More preferably, it is preferable to use Cu or a Cu alloy, Ag or an Ag alloy, gold (Au) or an Au alloy, Ni or a Ni alloy, Pd or a Pd alloy or the like, as an alternative to the Al or Al alloy electrode.

### EXAMPLES

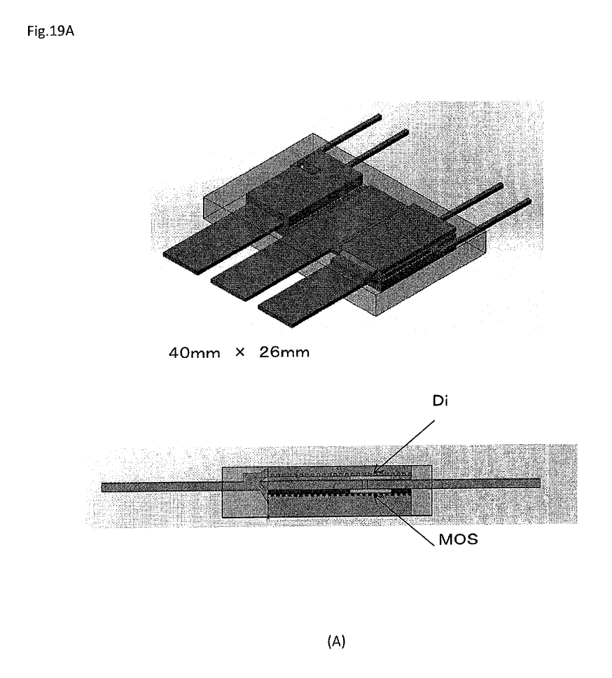

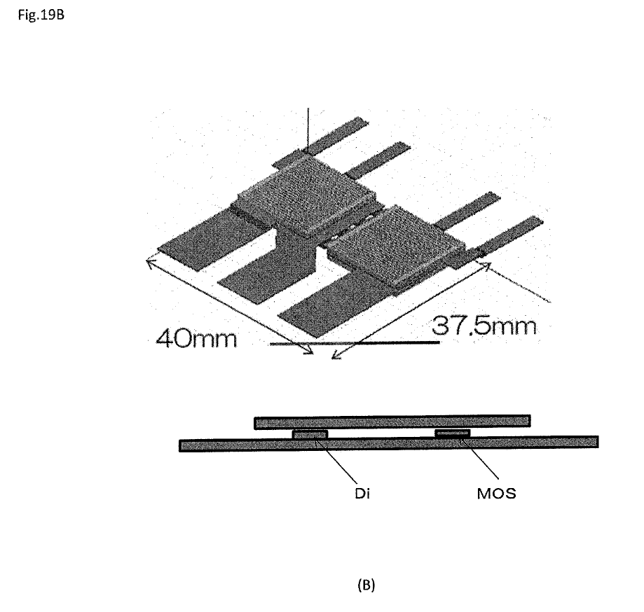

The respective characteristics were compared between a case where the switching elements and the diodes were stacked to be sterically mounted and a case where planarly mounted like the conventional case. FIGS. 19A and 19B are diagrams showing structures of semiconductor devices in the case where sterically mounted and the case where planarly mounted, respectively. More specifically, FIG. 19A shows a structure in a case where a semiconductor device was sterically mounted, and FIG. 19B shows a structure in a case where a semiconductor device was planarly mounted.

The results of a projected area ratio, a parasitic inductance ratio, and a thermal resistance ratio which were analyzed in the semiconductor devices having the respective structures shown in FIGS. 19A and 19B are shown in the following table.

TABLE 1

| | Three- | |
|---|---|---|
| | Dimensional Mounting | Planar Mounting |
| | (Present Invention) | (Conventional) |
| Projected Area Ratio | 0.7 | 1 |
| Parasitic Inductance Ratio | 0.49 | 1 |
| Thermal Resistance Ratio | 1.18 | 1 |

As apparent from Table 1, the values of the projected area ratio and the parasitic inductance ratio in the case of performing the three-dimensional mounting of the present invention are smaller as compared with the case of performing the planar mounting. That is, performing the three-dimensional mounting as in the semiconductor device of the present invention makes it possible to reduce the projected area ratio and the parasitic inductance ratio and to make the semiconductor device compact. With respect to the thermal resistance ratio, although not shown in Table 1, its analysis result was “2.0” in a case where the switching element SW1 and the switching element SW2 were stacked adjacently to each other in a vertical direction, showing that heat generation was very large. In contrast, although the thermal resistance ratio in the semiconductor device of the present invention was somewhat larger than that in the case of the conventional planar mounting, it revealed significant improvement as compared with the case where the switching elements were stacked adjacently to each other in a vertical direction. Therefore, the semiconductor device of the present invention can realize a highly-balanced high-performance semiconductor device as compared with the conventional planar mounting and the three-dimensional mounting in which the switching elements are adjacently stacked in a vertical direction.

Next, an example in which a stacked structure of a set of SiC diode and SiC MOSFET was mounted using a dedicated lead frame for plating connection and evaluation was performed thereon will be described.

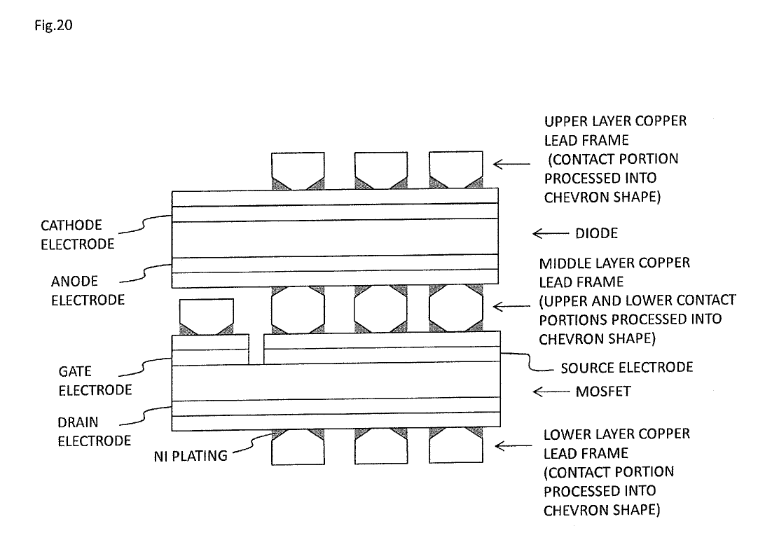

FIG. 20 is a schematic diagram showing a chip stack cross-section in a case where a MOSFET and a diode are mounted on a copper lead frame by plating joining. A diode chip (5×5 mm) having a thickness of 300 μm was placed on the upper side, and Ni and Ag metal were successively deposited on the cathode electrode. The contact portions of the upper layer copper lead frame were processed into a chevron shape, and the leads and the cathode electrode were connected by performing Ni plating on the gap between the upper layer copper lead frame and the cathode electrode. The Ni plating solution was circulated between the copper leads and sufficiently supplied to the portion to be plated. Al was deposited on the anode electrode, Ni was further deposited on the resultant layer, and an Au film was further deposited on the resultant layer to form the outermost layer of the anode electrode.

A MOSFET chip (5×5 mm) having a thickness of 300 μm was placed on the lower side, and Ni and Au metal were successively deposited on the drain electrode. The contact portions of the lower layer copper lead frame were processed into a chevron shape, and the leads and the drain electrode were connected by performing Ni plating on the gap between the lower layer copper lead frame and the drain electrode. Al was deposited on the source electrode, Ni was further deposited on the resultant layer, and an Au film was further deposited on the resultant layer to form the outermost layer of the source electrode.

The anode electrode of the diode and the source electrode of the MOSFET were brought into contact with the upper and lower chevron-shaped portions of the intermediate lead frame (in FIG. 20, referred to as the middle layer copper lead frame), respectively, and the gap therebetween was Ni-plated to connect both electrodes. The gate electrode of the MOSFET was connected to the dedicated lead frame lead terminal by plating, independently of the other electrodes. Although the angle of the chevron shape of the leads of each lead frame from the horizontal was set to 10 degrees, it was confirmed that good connection could be made for the angles of 5 degrees and 3 degrees to shorten plating time.

In the above Ni plating connection, a temporary fixing jig having a stacked structure was used to bring the respective connecting portions into contact, and simultaneous collective plating connection was performed in the plating bath. At this time, the surface treatment for preventing plating from being deposited was selectively performed in advance on the portions where plating was not needed to be deposited.

The Ni plating solution was a sulfamic acid Ni bath which can be relatively expected to reduce plating internal stress, and the plating temperature was 55° C. Further, the thickness of the lead frame, including the chevron-shaped portion, was set to be in the range of 200 μm to 500 μm. Further, the lead width was set to be 300 μm. It was heated to 350° C. after joining, and the electric characteristics were evaluated during the heating and after the heating, and it was confirmed that the device was normally operating.

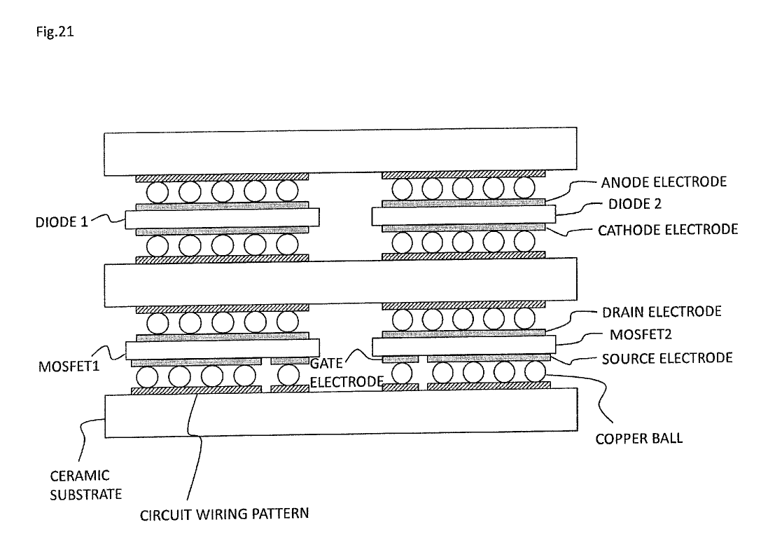

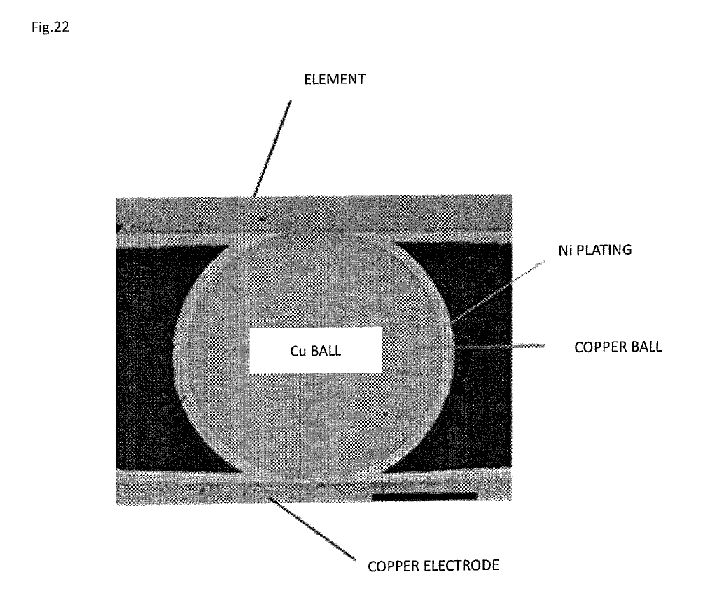

FIG. 21 is a diagram showing an example of a plating connection structure using the same SiC chip as described above and a ceramic substrate. Copper balls (250 ping)) were placed between the connecting electrodes, and the gap between every electrodes around the ball contact portion was filled with Ni plating to connect the electrodes. The average plating thickness was approximately 20 μm. FIG. 22 is a view showing an observation case (optical microscopic photograph) of a cross-section of a joined portion by Ni plating between electrodes using a ball.

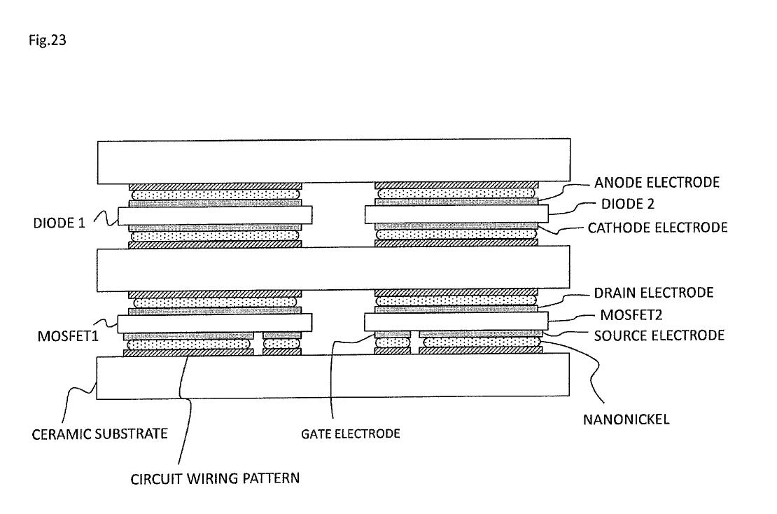

FIG. 23 is a schematic diagram explaining an example of a three-dimensional joining structure using a ceramic substrate. The joining was performed with a nano-sized nickel particle (average particle size 60 nmφ) paste. The nano nickel paste was applied to the joining surface, and the electrodes were crimped and fixed to each other and then heated in an inert gas atmosphere at 300° C. for 30 minutes. The size of each chip element was 5×5 mm and the outer size of the ceramic substrate was 15×20 mm. Reduction in size (⅓ or less) was made possible as compared with the planar arrangement. Further, as a result of measurement of the parasitic inductance L, it was found to be approximately ½ as compared with the planar arrangement.

1. A semiconductor device comprising:
a first switching element that is provided on a high side;
a first diode element that is connected in parallel to the first switching element;
a second switching element that is provide on a low side and connected in series to the first switching element; and
a second diode element that is connected in parallel to the second switching element, wherein
the first switching element and one of the first diode element and the second diode element are stacked adjacently to each other in a vertical direction of respective electrode surfaces thereof via a conductive electrode,
the second switching element and the other of the first diode element and the second diode element that is different from the diode element adjacent to the first switching element are stacked adjacently to each other in a vertical direction of respective electrode surfaces thereof via a conductive electrode, and
the first switching element and the second switching element are not adjacent in a vertical direction of respective electrode surfaces thereof.

2. The semiconductor device according to claim 1, further comprising:
a heat radiation plate that radiates heat generated in the first switching element and the second switching element, wherein
either one of electrode surfaces of the first switching element and/or either one of electrode surfaces of the second switching element is adjacent to the heat radiation plate.

3. The semiconductor device according to claim 1, wherein
the first diode element and the second diode element are formed of a silicon carbide (SiC) or gallium nitride (GaN) substrate.

4. The semiconductor device according to claim 1, wherein
the first switching element, the first diode element, the second switching element, and the second diode element are electrically connected to the conductive electrode by a conductive paste or plating.

5. The semiconductor device according to claim 4, wherein
a melting point T of the conductive paste, a material of the plating, and a metal of the electrode surface satisfies T/2>500 (K).
